(19) United States
(12) Patent Application Publication
(10) Pub. No.: US 2023/0413434 A1
(43) Pub. Date: Dec. 21, 2023

(54) CIRCUIT BOARD WITH LOWER DIELECTRIC CONSTANT AND ELECTRICAL CONNECTOR HAVING THE SAME

(71) Applicant: DONGGUAN LUXSHARE TECHNOLOGIES CO., LTD, Dongguan City (CN)

(72) Inventors: Zhaolong ZENG, Dongguan City (CN); Yixinchen XIAN, Dongguan City (CN); Ming LI, Dongguan City (CN); Kun LIU, Dongguan City (CN); Kaide WANG, Dongguan City (CN); Qiongnan CHEN, Dongguan City (CN)

(73) Assignee: DONGGUAN LUXSHARE TECHNOLOGIES CO., LTD, Dongguan City (CN)

(21) Appl. No.: 18/100,851

(22) Filed: Jan. 24, 2023

(30) Foreign Application Priority Data
Jun. 21, 2022 (CN) 202210701108.8

(51) Int. Cl. H05K 1/11; H05K 1/02

(52) U.S. Cl. CPC H05K 1/111; H05K 1/0219

(57) ABSTRACT

A circuit board includes a first surface, a second surface and a number of metal pads. The metal pads are arranged on the first surface and/or the second surface. The metal pads on a same side of the circuit board are arranged at intervals along a first direction. The metal pads include a first ground metal pad, a second ground metal pad and a signal metal pad. The circuit board further includes an adjustment opening. The adjustment opening is located beside the signal metal pad along the first direction and is close to the signal metal pad. The adjustment opening is configured to reduce the dielectric constant of the circuit board to improve high frequency performance of at least part of the metal pads. An electrical connector having the circuit board is also disclosed.

### CROSS-REFERENCE TO RELATED APPLICATION

This patent application claims priority of a Chinese Patent Application No. 202210701108.8, filed on Jun. 21, 2022 and titled “CIRCUIT BOARD AND ELECTRICAL CONNECTOR HAVING THE SAME”, the entire content of which is incorporated herein by reference

### TECHNICAL FIELD

The present disclosure relates to a circuit board and an electrical connector, which belongs to a technical field of connectors.

### BACKGROUND

With the continuous development of connector technologies, electrical connectors with printed circuit boards (PCBs) as built-in circuit boards are becoming more and more common. Considering the compatibility of products among various manufacturers, the size and tolerance design of the metal pads on the printed circuit board are often limited in the industry specification of the electrical connector. Although this limitation ensures the compatibility of the products, it also limits the improvement of the transmission quality of high-frequency signals at interconnection points to some extent.

It is known that the dielectric constant between the metal pads on a printed circuit board depends on the choice of the raw material of the printed circuit board. Due to the limitation of material development, there is limited performance improvement between metal pads by changing the materials of printed circuit boards. In addition, using the printed circuit boards of different materials to meet the performance requirements between the metal pads will greatly increase the number of part numbers, and the cost will be higher.

### SUMMARY

An object of the present disclosure is to provide a circuit board with lower cost and lower dielectric constant, and an electrical connector having the circuit board.

In order to achieve the above object, the present disclosure adopts the following technical solution: a circuit board, including: a first surface; a second surface opposite to the first surface, the circuit board including a thickness defined by the first surface and the second surface; and a plurality of metal pads which are arranged on the first surface and/or the second surface; wherein the plurality of metal pads located on a same side of the circuit board are arranged at intervals along a first direction, the plurality of metal pads located on the same side of the circuit board include a first ground metal pad, a second ground metal pad, and a signal metal pad located between the first ground metal pad and the second ground metal pad; and wherein the circuit board further includes an adjustment opening extending through the first surface and/or the second surface along a thickness direction of the circuit board, and the adjustment opening is located beside the signal metal pad along the first direction and is adjacent to the signal metal pad.

In order to achieve the above object, the present disclosure adopts the following technical solution: an electrical connector, including a tongue plate, the tongue plate being configured to be mated with a mating electrical connector, the tongue plate including a circuit board, the circuit board including: a first surface; a second surface opposite to the first surface, the circuit board including a thickness defined by the first surface and the second surface; and a plurality of metal pads which are arranged on the first surface and/or the second surface; wherein the plurality of metal pads located on a same side of the circuit board are arranged at intervals along a first direction, the plurality of metal pads located on the same side of the circuit board include a first ground metal pad, a second ground metal pad, and a signal metal pad located between the first ground metal pad and the second ground metal pad; and wherein the circuit board further includes an adjustment opening extending through the first surface and/or the second surface along a thickness direction of the circuit board, and the adjustment opening is located beside the signal metal pad along the first direction and is adjacent to the signal metal pad.

Compared with the prior art, the present disclosure provides the adjustment opening through the first surface and/or the second surface along the thickness direction of the circuit board. The adjustment opening is located beside the signal metal pad along the first direction and is adjacent to the signal metal pad. The adjustment opening is configured to reduce the dielectric constant of the circuit board in order to improve high frequency performance of at least part of the plurality of metal pads. With this arrangement, the present disclosure does not need to fundamentally change the material of the circuit board, thereby saving costs.

### BRIEF DESCRIPTION OF DRAWINGS

FIG. 1 is a schematic perspective view of a circuit board in accordance with an embodiment of the present disclosure;

FIG. 2 is a schematic perspective view of FIG. 1 from another angle;

FIG. 3 is a top view of FIG. 1;

FIG. 4 is a partial enlarged view of a circled portion A in FIG. 1;

FIG. 5 is a partial enlarged view of a framed portion B in FIG. 3;

FIG. 6 is a partial enlarged view of FIG. 5 in accordance with another embodiment of the present disclosure;

FIG. 7 is a schematic cross-sectional view taken along line C-C of FIG. 3;

FIG. 8 is a partial enlarged view of a framed portion D in FIG. 7;

FIG. 9 is a partial enlarged view of FIG. 8 in accordance with another embodiment of the present disclosure;

FIG. 10 is a partial enlarged view of FIG. 8 in accordance with another embodiment of the present disclosure;

FIG. 11 is a schematic view of an electrical connector in accordance with an embodiment of the present disclosure; and

FIG. 12 is a schematic view of the electrical connector in accordance with another embodiment of the present disclosure.

### DETAILED DESCRIPTION

Exemplary embodiments will be described in detail here, examples of which are shown in drawings. When referring to the drawings below, unless otherwise indicated, same numerals in different drawings represent the same or similar elements. The examples described in the following exemplary embodiments do not represent all embodiments consistent with this application. Rather, they are merely examples of devices and methods consistent with some aspects of the application as detailed in the appended claims.

The terminology used in this application is only for the purpose of describing particular embodiments, and is not intended to limit this application. The singular forms “a”, “said”, and “the” used in this application and the appended claims are also intended to include plural forms unless the context clearly indicates other meanings.

It should be understood that the terms “first”, “second” and similar words used in the specification and claims of this application do not represent any order, quantity or importance, but are only used to distinguish different components. Similarly, “an” or “a” and other similar words do not mean a quantity limit, but mean that there is at least one; “multiple” or “a plurality of” means two or more than two. Unless otherwise noted, “front”, “rear”, “lower” and/or “upper” and similar words are for ease of description only and are not limited to one location or one spatial orientation. Similar words such as “include” or “comprise” mean that elements or objects appear before “include” or “comprise” cover elements or objects listed after “include” or “comprise” and their equivalents, and do not exclude other elements or objects. The term “a plurality of” mentioned in the present disclosure includes two or more.

Hereinafter, some embodiments of the present disclosure will be described in detail with reference to the accompanying drawings. In the case of no conflict, the following embodiments and features in the embodiments can be combined with each other.

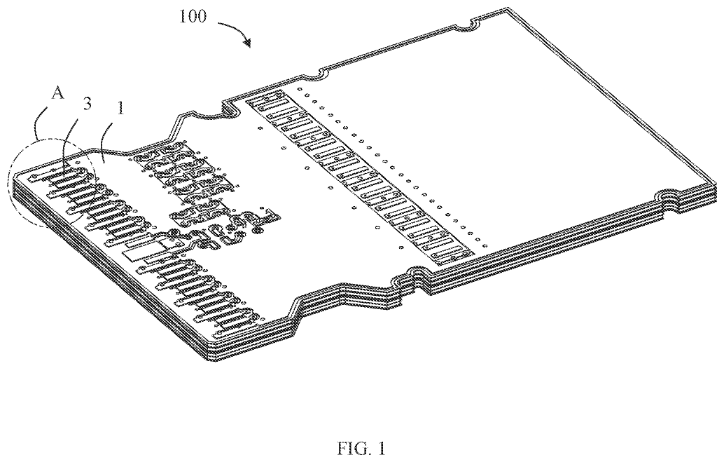

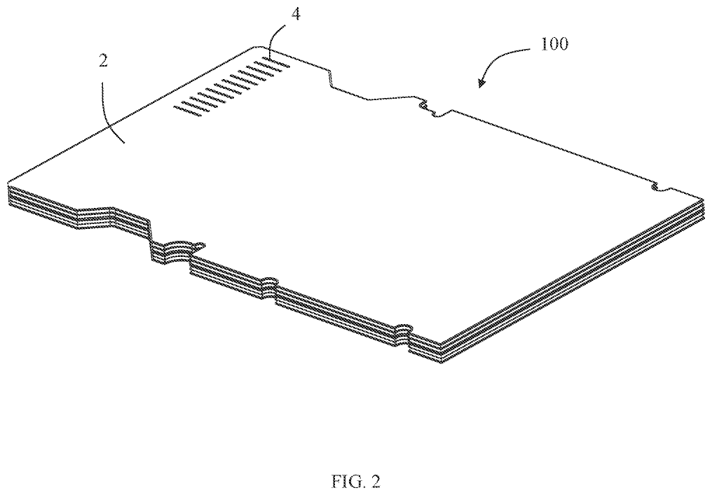

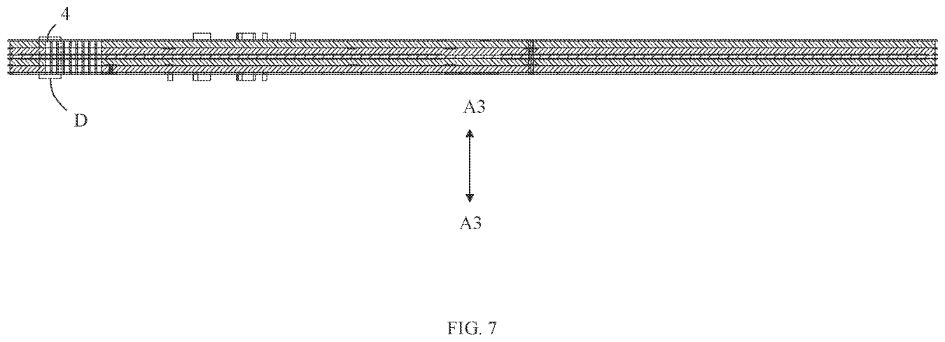

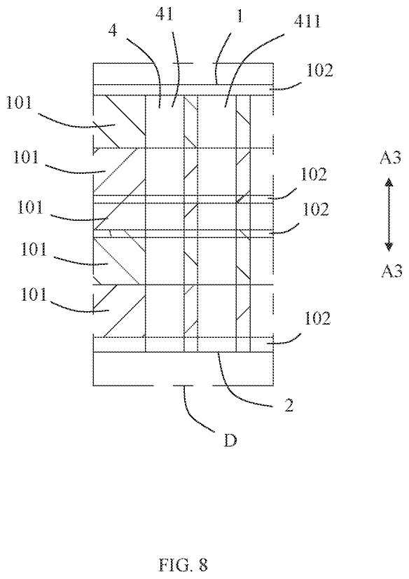

Referring to FIG. 1 and FIG. 2, the present disclosure discloses a circuit board 100 including a first surface 1 and a second surface 2 opposite to the first surface 1. The circuit board 100 includes a thickness defined by the first surface 1 and the second surface 2. In the illustrated embodiments of the present disclosure, the circuit board 100 is a printed circuit board. The circuit board 100 includes a plurality of metal pads 3 disposed on the first surface 1 and/or the second surface 2. In other words, the plurality of metal pads 3 are provided on one side or both sides of the circuit board 100. In the embodiment shown in the present disclosure, the plurality of metal pads 3 are only disposed on the first surface 1. The circuit board 100 may be a single-layer board or a multi-layer board. Referring to FIG. 7 and FIG. 8, in the embodiment shown in the present disclosure, the circuit board 100 is a multi-layer board. The circuit board 100 includes a plurality of dielectric layers 101 and a plurality of conductive layers 102. Each conductive layer 102 is located on a surface of a corresponding dielectric layer 101. The dielectric layers 101 are used to maintain the insulation among lines and layers, and are also referred to as “substrates”. The conductive layer 102 includes lines and drawings to form electrical connections of corresponding parts.

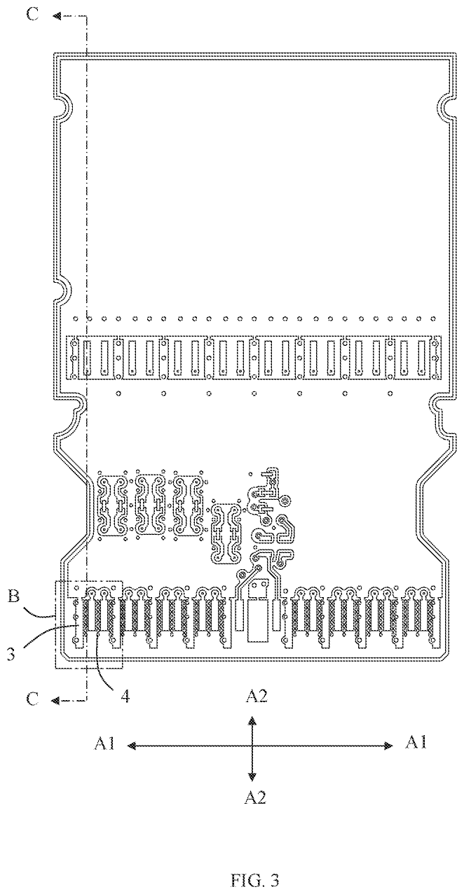

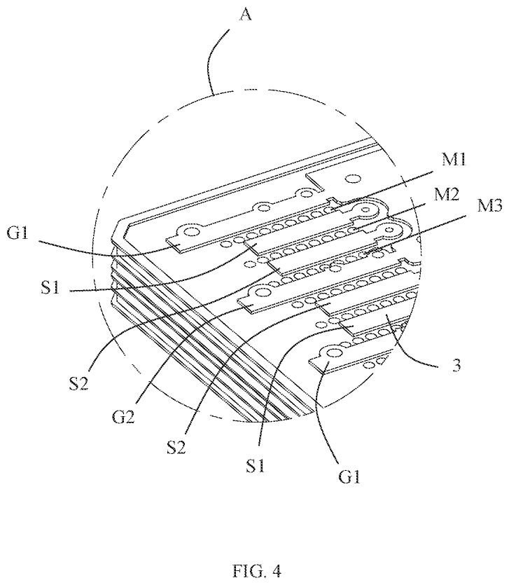

Referring to FIG. 3 to FIG. 5, the plurality of metal pads 3 located on a same side (e.g., a top surface) of the circuit board 100 are arranged at intervals along a first direction A1-A1 (e.g., a left-right direction). The plurality of metal pads 3 located on the same side of the circuit board 100 include a first ground metal pad G1, a second ground metal pad G2, and a signal metal pad S located between the first ground metal pad G1 and the second ground metal pad G2. In the embodiment shown in the present disclosure, the signal metal pad S includes a first signal metal pad S1 and a second signal metal pad S2 which are adjacently disposed along the first direction A1-A1. The first signal metal pad S1 and the second signal metal pad S2 form a differential pair DP (Differential Pair). The differential pair DP is configured to transmit differential signals. The first signal metal pad S1 and the second signal metal pad S2 are located between the first ground metal pad G1 and the second ground metal pad G2 along the first direction A1-A1. The first signal metal pad S1 is disposed adjacent to the first ground metal pad G1 along the first direction A1-A1. The second signal metal pad S2 is disposed adjacent to the second ground metal pad G2 along the first direction A1-A1. In other words, the first ground metal pad G1, the second ground metal pad G2, the first signal metal pad S1, and the second signal metal pad S2 are arranged in a manner of G1-S1-S2-G2 along the first direction A1-A1. In this way, two sides of the differential pair DP are respectively provided with one first ground metal pad G1 and one second ground metal pad G2 so as to improve the transmission effect.

In the embodiment shown in the present disclosure, the plurality of metal pads 3 include a plurality of differential pairs DPs, a plurality of first ground metal pads G1 and a plurality of second ground metal pads G2. One first ground metal pad G1 and one second ground metal pad G2 are provided on adjacent two sides of each differential pair DP along the first direction A1-A1. The following description only takes a group of G1-S1-S2-G2 as an example.

The metal pad 3 extends along a second direction A2-A2 perpendicular to the first direction A1-A1. The first signal metal pad S1 includes a rectangular first mating portion 31. A length of the first mating portion 31 along the second direction A2-A2 is L1. The second signal metal pad S2 includes a rectangular second mating portion 32. A length of the second mating portion 32 along the second direction A2-A2 is L2. The first ground metal pad G1 includes a substantially rectangular third mating portion 33. A length of the third mating portion 33 along the second direction A2-A2 is L3. The second ground metal pad G2 includes a substantially rectangular fourth mating portion 34. A length of the fourth mating portion 34 along the second direction A2-A2 is L4. The third mating portion 33 and the fourth mating portion 34 both extend beyond the first mating portion 31 and the second mating portion 32 along the second direction A2-A2; wherein, L1=L2, L3=L4, and L3>L1. Such setting is beneficial to improve the quality of signal transmission.

In the embodiment shown in the present disclosure, the third mating portion 33 of the first ground metal pad G1 is provided with a first protrusion 331 which protrudes away from the first mating portion 31 of the first signal metal pad S1 along the first direction A1-A1. The fourth mating portion 34 of the second ground metal pad G2 is provided with a second protrusion 341 which protrudes toward the second mating portion 32 of the second signal metal pad S2 along the first direction A1-A1. When the first surface 1 and the second surface 2 of the circuit board 100 are provided with the plurality of metal pads 3, the ground metal pads (e.g., upper ground metal pads) on the first surface 1 may not be completely aligned with the ground metal pads (e.g., lower ground metal pads) on the second surface 2 in a thickness direction A3-A3 of the circuit board 100. Therefore, by arranging the first protrusion 331 and the second protrusion 341, the upper ground metal pads and the lower ground metal pads can be better connected through adjustment, so as to have a better grounding shielding effect.

In the embodiment shown in the present disclosure, the circuit board 100 further includes an adjustment opening 4 extending through the first surface 1 and/or the second surface 2 along the thickness direction A3-A3 of the circuit board 100. The adjustment opening 4 is located beside and adjacent to the signal metal pad S along the first direction A1-A1. The adjustment opening 4 is configured to reduce the dielectric constant of the circuit board 100 so as to improve the high frequency performance of at least part of the plurality of metal pads 3. In the embodiment shown in the present disclosure, the high-frequency performance of an area jointly formed by the first ground metal pad G1, the second ground metal pad G2, and the first signal metal pad S1 and the second signal metal pad S2 which are located between the adjacent first ground metal pad G1 and the second ground metal pad G2 can be improved. In an embodiment of the present disclosure, the improvement of the high-frequency performance refers to improving the high-frequency return loss and attenuation resonance performance by improving the impedance continuity of the region.

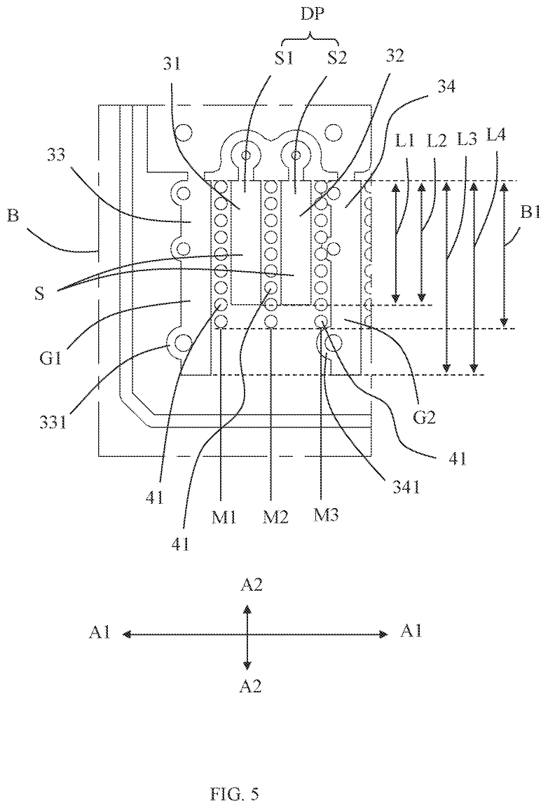

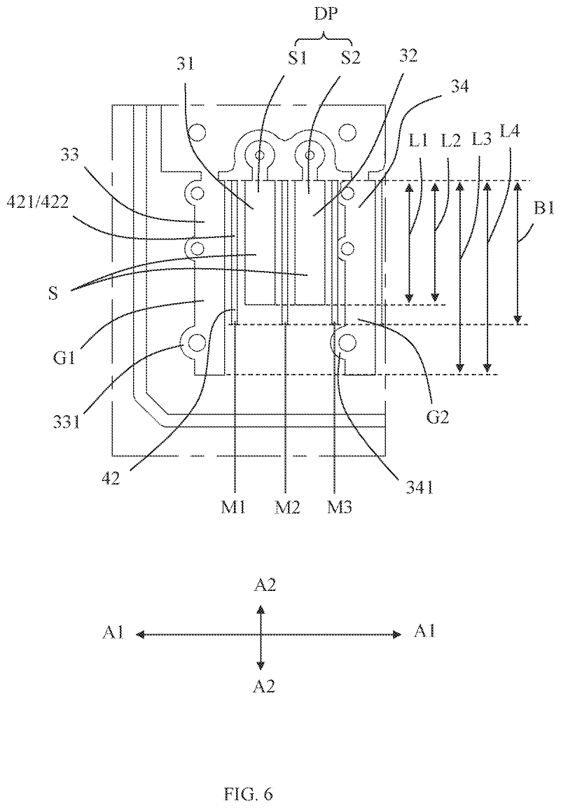

Referring to FIG. 5 and FIG. 6, in the embodiment shown in the present disclosure, the signal metal pad S is rectangular. A span B1 of the adjustment opening 4 along the second direction A2-A2 is greater than the length L1 of the first mating portion 31 along the second direction A2-A2. The span B1 of the adjustment opening 4 along the second direction A2-A2 is also greater than the length L2 of the second mating portion 32 along the second direction A2-A2. The adjustment openings 4 include a first row of adjustment openings M1, a second row of adjustment openings M2 and a third row of adjustment openings M3. The first row of adjustment openings M1, the second row of adjustment openings M2 and the third row of adjustment openings M3 are spaced along the first direction A1-A1. Each row of adjustment openings extends along the second direction A2-A2. The first row of adjustment openings M1 is located between the first signal metal pad S1 and the first ground metal pad G1 along the first direction A1-A1. The second row of adjustment openings M2 is located between the first signal metal pad S1 and the second signal metal pad S2 along the first direction A1-A1. The third row of adjustment openings M3 is located between the second signal metal pad S2 and the second ground metal pad G2 along the first direction A1-A1.

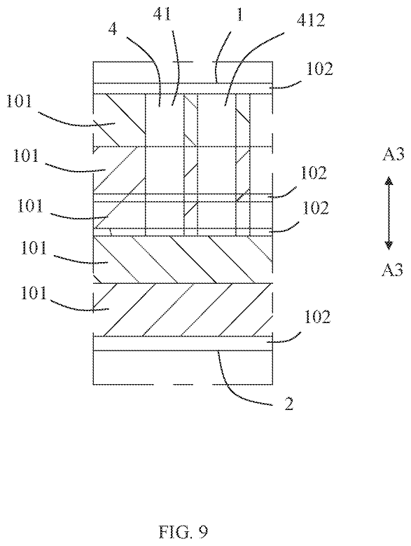

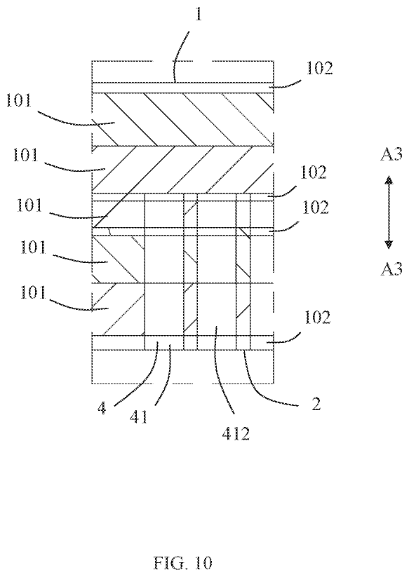

Referring to FIG. 5, in an embodiment of the present disclosure, the adjustment opening 4 includes a plurality of holes 41 spaced along the second direction A2-A2. Referring to FIG. 8 to FIG. 10, the holes 41 are through holes 411 extending through the first surface 1 and the second surface 1 along the thickness direction A3-A3 of the circuit board 100. Alternatively, the holes 41 are blind holes 412 extending through the first surface 1 but not through the second surface 2 along the thickness direction A3-A3 of the circuit board 100, or the holes 41 are blind holes 412 extending through the second surface 2 but not through the first surface 1. The blind holes 412 have a certain depth. The blind holes 412 can be drilled from one side of the circuit board 100, or can be drilled from both sides of the circuit board 100 simultaneously.

Referring to FIG. 6, in another embodiment of the present disclosure, the adjustment opening 4 includes a slot 42 disposed along the second direction A2-A2. The slot 42 is a through slot 421 extending through the first surface 1 and the second surface 2 along the thickness direction A3-A3 of the circuit board 100. Alternatively, the slot 42 is a blind slot 422 extending through the first surface 1 but not through the second surface 2 along the thickness direction A3-A3 of the circuit board 100, or the slot 42 is a blind slot 422 extending through the second surface 2 but not through the first surface 1. The blind slot 422 has a certain depth. The blind slot 422 may be slotted from one side of the circuit board 100, or may be slotted from both sides of the circuit board 100 simultaneously.

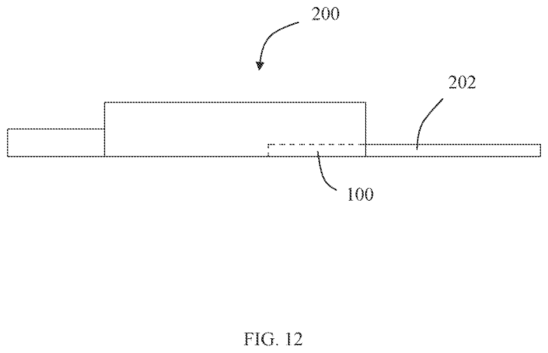

The first ground metal pad G1, the second ground metal pad G2 and the signal metal pad S are configured to be in contact with conductive terminals (not shown) of a mating connector. Of course, referring to FIG. 12, in other embodiments, the first ground metal pad G1, the second ground metal pad G2 and the signal metal pad S may also be configured to be connected to a cable 202, for example by soldering or welding.

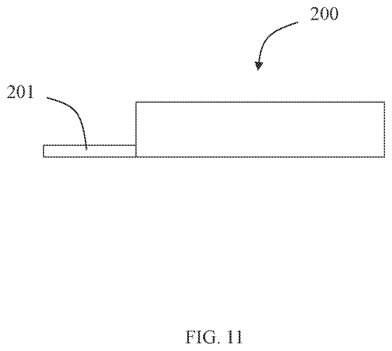

Referring to FIG. 11, the present disclosure further relates to an electrical connector 200 including a tongue plate 201. The tongue plate 201 is configured to mate with the mating connector. The tongue plate 201 includes the circuit board 100. The metal pads 3 are exposed on the tongue plate 201 and are used to contact the conductive terminals of the mating connector. Referring to FIG. 12, in another embodiment of the present disclosure, the electrical connector 200 includes the circuit board 100 and the cable 202 connected to the circuit board 100, for example by soldering or welding.

Compared with the prior art, the present disclosure can introduce air by arranging the adjustment opening 4 adjacent to the signal metal pad S, thereby reducing the dielectric constant between at least part of the metal pads 3. The present disclosure improves the high-frequency performance between the metal pads 3, enables the high-frequency performance of each point in the link to achieve better continuity, and improves the transmission quality of the signal.

The above embodiments are only used to illustrate the present disclosure and not to limit the technical solutions described in the present disclosure. The understanding of this specification should be based on those skilled in the art. Descriptions of directions, although they have been described in detail in the above-mentioned embodiments of the present disclosure, those skilled in the art should understand that modifications or equivalent substitutions can still be made to the application, and all technical solutions and improvements that do not depart from the spirit and scope of the application should be covered by the claims of the application.

What is claimed is:

1. A circuit board, comprising:
a first surface;
a second surface opposite to the first surface, the circuit board comprising a thickness defined by the first surface and the second surface; and
a plurality of metal pads which are arranged on the first surface and/or the second surface;
wherein the plurality of metal pads located on a same side of the circuit board are arranged at intervals along a first direction, the plurality of metal pads located on the same side of the circuit board comprise a first ground metal pad, a second ground metal pad, and a signal metal pad located between the first ground metal pad and the second ground metal pad; and
wherein the circuit board further comprises an adjustment opening extending through the first surface and/or the second surface along a thickness direction of the circuit board, and the adjustment opening is located beside the signal metal pad along the first direction and is adjacent to the signal metal pad.

2. The circuit board according to claim 1, wherein the signal metal pad extends in a second direction perpendicular to the first direction; and
wherein the adjustment opening comprises a plurality of holes spaced along the second direction; or the adjustment opening comprises a slot extending along the second direction.

3. The circuit board according to claim 2, wherein the holes are through holes extending through the first surface and the second surface along the thickness direction of the circuit board; or
the holes are blind holes extending through the first surface but not extending through the second surface along the thickness direction of the circuit board; or the holes are blind holes extending through the second surface but not extending through the first surface along the thickness direction of the circuit board.

4. The circuit board according to claim 2, wherein the slot is a through slot extending through the first surface and the second surface along the thickness direction of the circuit board; or
the slot is a blind slot extending through the first surface but not extending through the second surface along the thickness direction of the circuit board; or the slot is a blind slot extending through the second surface but not extending through the first surface along the thickness direction of the circuit board.

5. The circuit board according to claim 2, wherein the signal metal pad comprises a first signal metal pad and a second signal metal pad which are adjacently arranged along the first direction, the first signal metal pad comprises a rectangular first mating portion, and a length of the first mating portion along the second direction is L1;
wherein the second signal metal pad comprises a rectangular second mating portion, and a length of the second mating portion along the second direction is L2; and
wherein a span of the adjustment opening along the second direction is greater than the length L1 of the first mating portion along the second direction; and the span of the adjustment opening along the second direction is also greater than the length L2 of the second mating portion along the second direction.

6. The circuit board according to claim 2, wherein the signal metal pad comprises a first signal metal pad and a second signal metal pad which are adjacently arranged along the first direction, the first signal metal pad and the second signal metal pad are configured to transmit differential signals, the first signal metal pad and the second signal metal pad are located between the first ground metal pad and the second ground metal pad along the first direction, the first signal metal pad is disposed adjacent to the first ground metal pad along the first direction, and the second signal metal pad is disposed adjacent to the second ground metal pad along the first direction.

7. The circuit board according to claim 6, wherein a plurality of the adjustment openings are provided, the adjustment openings comprise a first row of adjustment openings, a second row of adjustment openings and a third row of adjustment openings, the first row of adjustment openings, the second row of adjustment openings and the third row of adjustment openings are spaced along the first direction, each row of adjustment openings extends along the second direction, the first row of adjustment openings is located between the first signal metal pad and the first ground metal pad along the first direction, the second row of adjustment openings is located between the first signal metal pad and the second signal metal pad along the first direction, and the third row of adjustment openings is located between the second signal metal pad and the second ground metal pad along the first direction.

8. The circuit board according to claim 6, wherein the first signal metal pad comprises a rectangular first mating portion, and a length of the first mating portion along the second direction is L1;
the second signal metal pad comprises a rectangular second mating portion, and a length of the second mating portion along the second direction is L2;
the first ground metal pad comprises a third mating portion, and a length of the third mating portion along the second direction is L3;
the second ground metal pad comprises a fourth mating portion, and a length of the fourth mating portion along the second direction is L4; and wherein
both the third mating portion and the fourth mating portion extend beyond the first mating portion and the second mating portion along the second direction, wherein L1=L2, L3=L4, and L3>L1.

9. The circuit board according to claim 1, wherein the first ground metal pad, the second ground metal pad and the signal metal pad are configured to be in contact with conductive terminals of a mating electrical connector or to be connected to a cable.

10. The circuit board according to claim 1, wherein the adjustment opening is configured to lower a dielectric constant of the circuit board in order to improve high frequency performance of at least part of the plurality of metal pads.

11. An electrical connector, comprising a tongue plate, the tongue plate being configured to be mated with a mating electrical connector, the tongue plate comprising a circuit board, the circuit board comprising:
a first surface;
a second surface opposite to the first surface, the circuit board comprising a thickness defined by the first surface and the second surface; and
a plurality of metal pads which are arranged on the first surface and/or the second surface;
wherein the plurality of metal pads located on a same side of the circuit board are arranged at intervals along a first direction, the plurality of metal pads located on the same side of the circuit board comprise a first ground metal pad, a second ground metal pad, and a signal metal pad located between the first ground metal pad and the second ground metal pad; and
wherein the circuit board further comprises an adjustment opening extending through the first surface and/or the second surface along a thickness direction of the circuit board, and the adjustment opening is located beside the signal metal pad along the first direction and is adjacent to the signal metal pad.

12. The electrical connector according to claim 11, wherein the signal metal pad extends in a second direction perpendicular to the first direction; and
wherein the adjustment opening comprises a plurality of holes spaced along the second direction; or the adjustment opening comprises a slot extending along the second direction.

13. The electrical connector according to claim 12, wherein the holes are through holes extending through the first surface and the second surface along the thickness direction of the circuit board; or
the holes are blind holes extending through the first surface but not extending through the second surface along the thickness direction of the circuit board; or the holes are blind holes extending through the second surface but not extending through the first surface along the thickness direction of the circuit board.

14. The electrical connector according to claim 12, wherein the slot is a through slot extending through the first surface and the second surface along the thickness direction of the circuit board; or
the slot is a blind slot extending through the first surface but not extending through the second surface along the thickness direction of the circuit board; or the slot is a blind slot extending through the second surface but not extending through the first surface along the thickness direction of the circuit board.

15. The electrical connector according to claim 12, wherein the signal metal pad comprises a first signal metal pad and a second signal metal pad which are adjacently arranged along the first direction, the first signal metal pad comprises a rectangular first mating portion, and a length of the first mating portion along the second direction is L1;
wherein the second signal metal pad comprises a rectangular second mating portion, and a length of the second mating portion along the second direction is L2; and
wherein a span of the adjustment opening along the second direction is greater than the length L1 of the first mating portion along the second direction; and the span of the adjustment opening along the second direction is also greater than the length L2 of the second mating portion along the second direction.

16. The electrical connector according to claim 12, wherein the signal metal pad comprises a first signal metal pad and a second signal metal pad which are adjacently arranged along the first direction, the first signal metal pad and the second signal metal pad are configured to transmit differential signals, the first signal metal pad and the second signal metal pad are located between the first ground metal pad and the second ground metal pad along the first direction, the first signal metal pad is disposed adjacent to the first ground metal pad along the first direction, and the second signal metal pad is disposed adjacent to the second ground metal pad along the first direction.

17. The electrical connector according to claim 16, wherein a plurality of the adjustment openings are provided, the adjustment openings comprise a first row of adjustment openings, a second row of adjustment openings and a third row of adjustment openings, the first row of adjustment openings, the second row of adjustment openings and the third row of adjustment openings are spaced along the first direction, each row of adjustment openings extends along the second direction, the first row of adjustment openings is located between the first signal metal pad and the first ground metal pad along the first direction, the second row of adjustment openings is located between the first signal metal pad and the second signal metal pad along the first direction, and the third row of adjustment openings is located between the second signal metal pad and the second ground metal pad along the first direction.

18. The electrical connector according to claim 16, wherein the first signal metal pad comprises a rectangular first mating portion, and a length of the first mating portion along the second direction is L1;
the second signal metal pad comprises a rectangular second mating portion, and a length of the second mating portion along the second direction is L2;
the first ground metal pad comprises a third mating portion, and a length of the third mating portion along the second direction is L3;
the second ground metal pad comprises a fourth mating portion, and a length of the fourth mating portion along the second direction is L4; and wherein
both the third mating portion and the fourth mating portion extend beyond the first mating portion and the second mating portion along the second direction, wherein L1=L2, L3=L4, and L3>L1.

19. The electrical connector according to claim 11, wherein the first ground metal pad, the second ground metal pad and the signal metal pad are configured to be in contact with conductive terminals of a mating electrical connector or to be connected to a cable.

20. The electrical connector according to claim 11, wherein the adjustment opening is configured to lower a dielectric constant of the circuit board in order to improve high frequency performance of at least part of the plurality of metal pads.
